(19) United States
(12) Patent Application Publication
(10) Pub. No.: US 2023/0251570 A1
(43) Pub. Date: Aug. 10, 2023

(54) Selective Deprotection via Dye Diffusion

(71) Applicant: Tokyo Electron Limited, Tokyo (JP)

(72) Inventors: Michael Murphy, Latham, NY (US); Charlotte Cutler, Hopkinton, MA (US); David Conklin, Saratoga Springs, NY (US)

(21) Appl. No.: 18/166,598

(22) Filed: Feb. 9, 2023

Related U.S. Application Data
(60) Provisional application No. 63/308,701, filed on Feb. 10, 2022.

(51) Int. Cl. G03F 7/004; H01L 21/311; G03F 7/11; G03F 7/16

(52) U.S. Cl. CPC G03F 7/0048; H01L 21/31144; G03F 7/11; G03F 7/0045; G03F 7/168

(57) ABSTRACT

A method of patterning a substrate by selective deprotection via dye diffusion. The method includes forming a photoresist pattern on the substrate from a layer of photoresist deposited on the substrate, depositing a first overcoat on the photoresist pattern, the first overcoat filling openings defined by the photoresist pattern and covering the photoresist pattern, the first overcoat including an organic film containing a dye. The method further includes diffusing the dye from the first overcoat a predetermined diffusion length into the photoresist pattern, resulting in diffusion regions in the photoresist pattern, and removing the first overcoat from the substrate. The method further includes activating the solubility-shifting agent in the diffusion regions of the photoresist pattern using a second actinic radiation, depositing a second overcoat on the substrate, and developing the substrate with a second developer resulting in removal of soluble portions of the diffusion regions of the photoresist pattern.

### CROSS-REFERENCE TO RELATED APPLICATIONS

This application is related to and claims priority to U.S. Provisional Patent Application Ser. No. 62/308,701 filed on Feb. 10, 2022, the entire contents of which are herein incorporated by reference.

### TECHNICAL FIELD

This invention relates to microfabrication including microfabrication of integrated circuits as well as processes involved in patterning semiconductor substrates.

### BACKGROUND OF THE INVENTION

In material processing methodologies (such as photolithography), creating patterned layers typically involves the application of a thin layer of radiation-sensitive material, such as photoresist, to an upper surface of a substrate. This radiation-sensitive material is transformed into a patterned mask that can be used to etch or transfer a pattern into an underlying layer on a substrate. Patterning of the radiation-sensitive material generally involves exposure by a radiation source through a reticle (and associated optics) onto the radiation-sensitive material using, for example, a photolithographic exposure system. This exposure creates a latent pattern within the radiation-sensitive material which can then be developed. Developing refers to dissolving and removing a portion of the radiation-sensitive material to yield a relief pattern (topographic pattern). The portion of material removed can be either irradiated regions or non-irradiated regions of the radiation-sensitive material depending on a photoresist tone and/or type of developing solvent used. The relief pattern can then function as a mask layer defining a pattern.

Preparation and development of various films used for patterning can include thermal treatment or baking. For example, a newly applied film can receive a post-application bake (PAB) to evaporate solvents and/or to increase structural rigidity or etch resistance. Also, a post-exposure bake (PEB) can be executed to set a given pattern to prevent further dissolving. Fabrication tools for coating and developing substrates typically include one or more baking modules. Some photolithography processes include coating a substrate with a thin film of Bottom Anti-reflective Coating (BARC), followed by coating with a resist, and then exposing the substrate to a pattern of light as a process step for creating microchips. A relief pattern created can then be used as a mask or template for additional processing such as transferring the pattern into an underlying layer.

### SUMMARY

Ever continuous scaling requires improved patterning resolution. One approach is spacer technology to define a sub-resolution line feature via ALD (atomic layer deposition). One challenge, however, is that if the opposite tone feature is desired, using spacer techniques can be complex involving over-coating another material, chemical mechanical planarization (CMP), and reactive ion etch (RIE) to exhume the spacer material leaving a narrow trench, which can be costly.

Anti-spacer is a self-aligned technology that uses the diffusion length of a reactive species to define a critical dimension (CD), creating a narrow trench. With a reactive species controlled spatially via exposure through a mask, then instead of a narrow trench, a narrow slot contact can be formed. Instead of spatial control, reactive species can be controlled uniformly across a wafer by decomposition of a thermal acid generator via a bake process. A corresponding CD can be tuned through molecular weight modification of the reactive species, molecular structure of the reactive species, and the bake temperature and bake time. Additionally, the CD can be controlled by the composition of the material the reactive species is diffusing into. The polarity of components within the resin may affect acid diffusivity and the activation energy of the reactive-species sensitive component of the material is an additional means to control processing. These techniques enable access to narrow slot contact features at dimensions beyond the reach of advanced lithographic capabilities. But processing requires a “freeze” step, that is, a treatment that neutralizes a solubility shifting potential of a layer having an acid generator. Freeze processing, however, is not perfect and can reduce throughput.

According to an embodiment of the invention, a method of patterning a substrate includes forming a photoresist pattern on the substrate from a layer of photoresist deposited on the substrate, the layer of photoresist including a solubility-shifting agent, the photoresist pattern formed by activating the solubility-shifting agent using a pattern of first actinic radiation, and developing the substrate with a first developer resulting in removal of soluble portions of the layer of photoresist, depositing a first overcoat on the photoresist pattern, the first overcoat filling openings defined by the photoresist pattern and covering the photoresist pattern, the first overcoat including an organic film containing a dye, diffusing the dye from the first overcoat a predetermined diffusion length into the photoresist pattern, resulting in diffusion regions in the photoresist pattern, and removing the first overcoat from the substrate. The method further includes activating the solubility-shifting agent in the diffusion regions of the photoresist pattern using a second actinic radiation, the solubility-shifting agent activated sufficiently to meet the threshold of sensitivity in the diffusion regions without meeting the threshold of sensitivity of the photoresist pattern, depositing a second overcoat on the substrate, and developing the substrate with a second developer resulting in removal of soluble portions of the diffusion regions of the photoresist pattern, the second overcoat being insoluble in the second developer. According to one embodiment, the removal of the soluble portions of the diffusion regions of the photoresist pattern forms anti-spacer features between the remaining photoresist pattern and the second overcoat. The method can further includes transferring the anti-spacer features into an underlying layer through an etching process.

According to an embodiment of the invention, a method of patterning a substrate includes forming a photoresist pattern on the substrate from a layer of photoresist deposited on the substrate, the layer of photoresist including a solubility-shifting agent, the photoresist pattern formed by activating the solubility-shifting agent using a pattern of first actinic radiation, and developing the substrate with a first developer resulting in removal of soluble portions of the layer of photoresist, depositing a first overcoat on the photoresist pattern, the first overcoat filling openings defined by the photoresist pattern and covering the photoresist pattern, the first overcoat including an organic film containing a dye, diffusing the dye from the first overcoat a predetermined diffusion length into the photoresist pattern, resulting in first diffusion regions in the photoresist pattern, and removing the first overcoat from the substrate. The method further includes depositing a second overcoat on the substrate, activating the solubility-shifting agent in the first diffusion regions in the photoresist pattern using a second actinic radiation, and diffusing the solubility agent into the second overcoat resulting in second diffusion regions in the second overcoat, the solubility-shifting agent activated sufficiently to meet the threshold of sensitivity in the second diffusion regions without meeting the threshold of sensitivity of the second overcoat, and developing the substrate with a second developer resulting in removal of soluble portions of the second diffusion regions of the second overcoat, the second overcoat and the first diffusion regions in the photoresist pattern being insoluble in the second developer. According to one embodiment, the removal of the soluble portions of the second diffusion regions of the second overcoat forms anti-spacer features between the remaining first diffusion regions in the photoresist pattern and the second overcoat. The method can further includes transferring the anti-spacer features into an underlying layer through an etching process. According to another embodiment, the removal of soluble portions of the second diffusion regions forms airgap features in second overcoat.

Of course, the order of discussion of the different steps as described herein has been presented for clarity sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Note that this summary section does not specify every embodiment and/or incrementally novel aspect of the present disclosure or claimed invention. Instead, this summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

FIGS. 1A-1I show a substrate processing method for forming anti-spacer trenches according to one embodiment;

FIGS. 2A-2E show a substrate processing method for forming anti-spacer trenches according to another embodiment; and

FIGS. 3A-3F show a substrate processing method for forming airgaps in a film according to other embodiments.

### DETAILED DESCRIPTION

Techniques disclosed herein use a track-based solution for precise control of reaction depth within organic films through the use of diffusive dye molecules. The process locationally changes the transparency of a film via diffusion of dye from an external film, thereby controlling the depth with nanometer precision in which photochemical reactions occur in films or patterned features upon exposure.

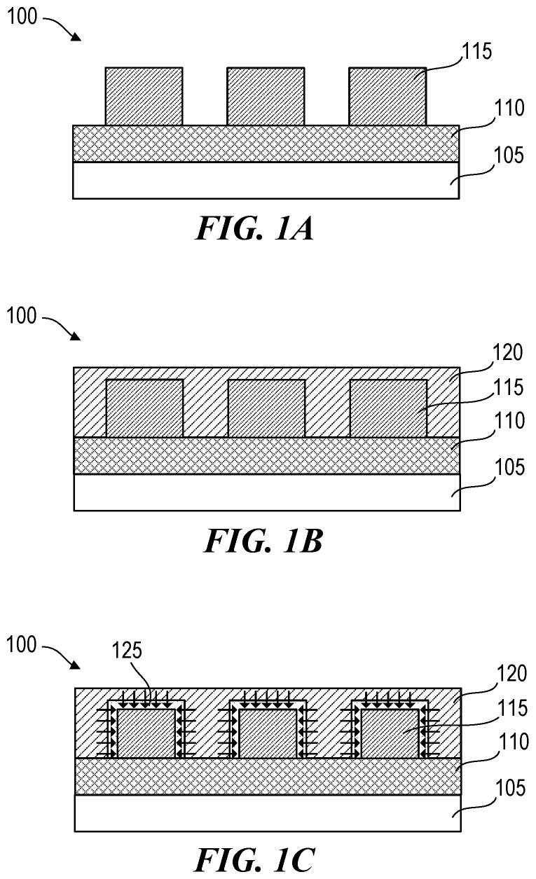

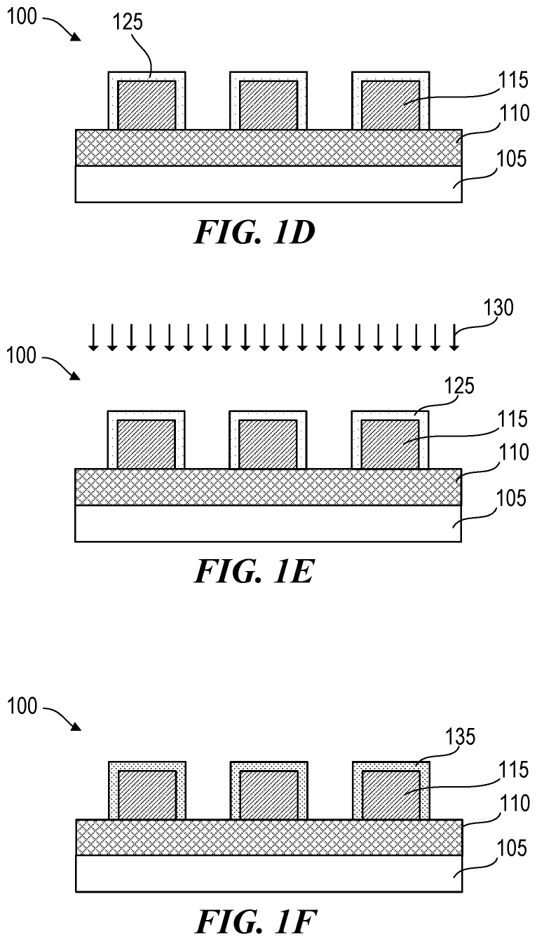

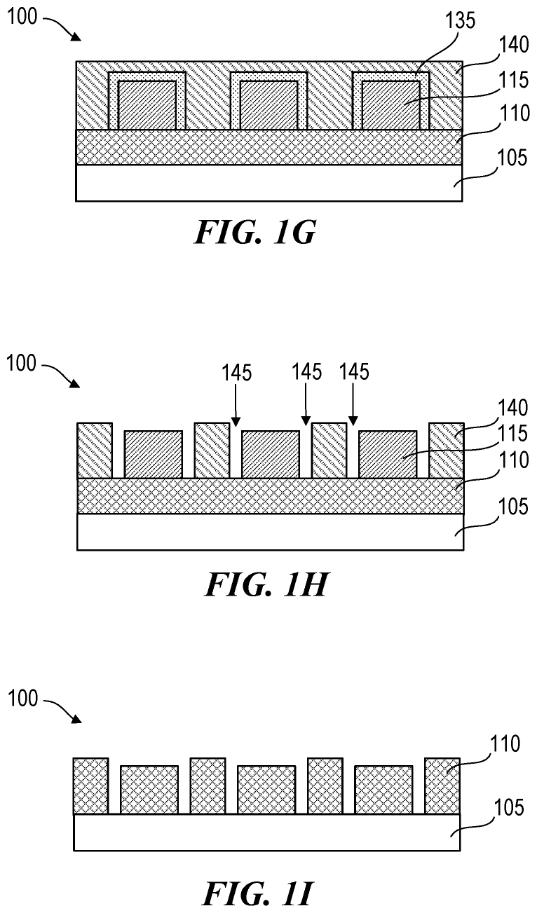

According to one embodiment, a process will be described in detail for the creation of anti-spacer trenches in a patterned photoresist. First, as illustrated in the side cross-sectional view FIG. 1A, a photoresist is patterned via photolithography on a substrate that includes creating a photoresist pattern 100 containing a series of nanoscale features 115 on an underlying layer 110 and a base layer 105. The photoresist pattern 100 is formed from a layer of photoresist deposited on the substrate, the layer of photoresist including a solubility-shifting agent, the photoresist pattern 100 formed by activating the solubility-shifting agent using a pattern of first actinic radiation, and developing the substrate with a first developer resulting in removal of soluble portions of the layer of photoresist. The layer of photoresist may be composed of, but is not limited to, an acid deprotectable resin, a photo-acid generator (PAG) and a quencher. The components are designed to meet transparency requirements defined by the wavelength of the incident photons to insure uniform absorption throughout the depth of the photoresist.

Next, as shown in FIG. 1B, an organic film, referred to as a first overcoat 120, is deposited over the photoresist pattern 100. The first overcoat 120 can be deposited by spin-on deposition. The first overcoat 120 fills openings defined by the photoresist pattern 100 as well as covers the photoresist pattern 100. Spin-on deposition typically results in an overburden region or thickness of material above top surfaces of features on the substrate. The formulation of the first overcoat 120 is cast in a solvent or blend of solvents to prevent dissolution of the underlying photoresist pattern 100 or intermixing of the two films. The first overcoat 120 may be composed of, but is not limited to, a resin and dye. The composition and concentration of the dye component is designed to meet photon absorption, diffusivity and reactivity requirements. Chosen dyes have high absorption cross-section and non-bleachable attributes at the specified wavelength. The dye may include an acid amplifier that decomposes in the presence of acid to generate more acid via acid-catalyzed mechanisms. Examples of acid amplifiers include compounds that generate fluorinated sulfonic acids upon decomposition.

Next, as shown in FIG. 1C, the following step is diffusion of the dye molecules from the first overcoat 120 into the photoresist pattern 100 via a bake step. The elevated temperature drives the dye molecules from the first overcoat 120 into the photoresist pattern 100 to a depth defined by the bake temperature, bake time, dye concentration and diffusivity of the dye. The predetermined diffusion length into the photoresist pattern results in diffusion regions 125 in the nanoscale features 115 of the photoresist pattern 100.

Next, as shown in FIG. 1D, the substrate is washed in a solvent system chosen to remove the first overcoat 120 selective to the photoresist pattern 100. The solvent system may be aqueous or organic and is defined by the composition of the first overcoat resin.

After removal of first overcoat 120, the substrate undergoes a second lithographic exposure step shown in FIG. 1E. The exposure step activates the solubility-shifting agent in the diffusion regions 125 of the photoresist pattern 100 using a second actinic radiation 130, where the solubility-shifting agent is activated sufficiently to meet the threshold of sensitivity in the diffusion regions 125 without meeting the threshold of sensitivity of the photoresist pattern 100. In the exposure step, the majority of the photons absorb in the region of the patterned features diffused with the dye. The exposure dose is defined to achieve the critical number of PAG decomposition reactions necessary for a solubility shift in the dye-infused region. The presence of the dye reduces the number of PAG-photon interactions within the body of the pattern.

Next, post exposure, the activation step further includes baking the substrate as at an elevated temperature to drive deprotection of the resin via reaction with the photo generated acid. The disparity in PAG decomposition from the dye infused region to the body of the pattern allows for selective deprotection of the dye infused region. The resulting diffusion regions 135 are shown in FIG. 1F.

Next, an organic film, referred to as second overcoat 140, is deposited over the photoresist pattern 100 as shown in FIG. 1G, the second overcoat 140 filling openings defined by the photoresist pattern 100 and covering the photoresist pattern 100. The formulation of second overcoat 140 is cast in a solvent or blend of solvents to prevent dissolution of the underlying photoresist or intermixing of the two films. The second overcoat 140 is composed of a resin designed to have a low non-zero dissolution rate in aqueous developer such as tetramethyl ammonium hydroxide to controllably remove the film from overtop the photoresist pattern 100.

Next, the substrate is developed with a second developer resulting in removal of soluble portions of the diffusion regions 135 of the photoresist pattern 100, where the second overcoat 140 is essentially insoluble in the second developer. For example, the second developer can contain an aqueous medium recessing the second overcoat 140 and dissolving the portion of the photoresist which has exceeded the critical level of deprotection. As shown in FIG. 1H, an anti-spacer trench 145 is formed with a critical dimension defined by the dye diffusion length.

Next, the anti-spacer features may be etch transferred into the underlying layer 110 as shown in FIG. H. For example, the underlying layer 110 may include a hardmask.

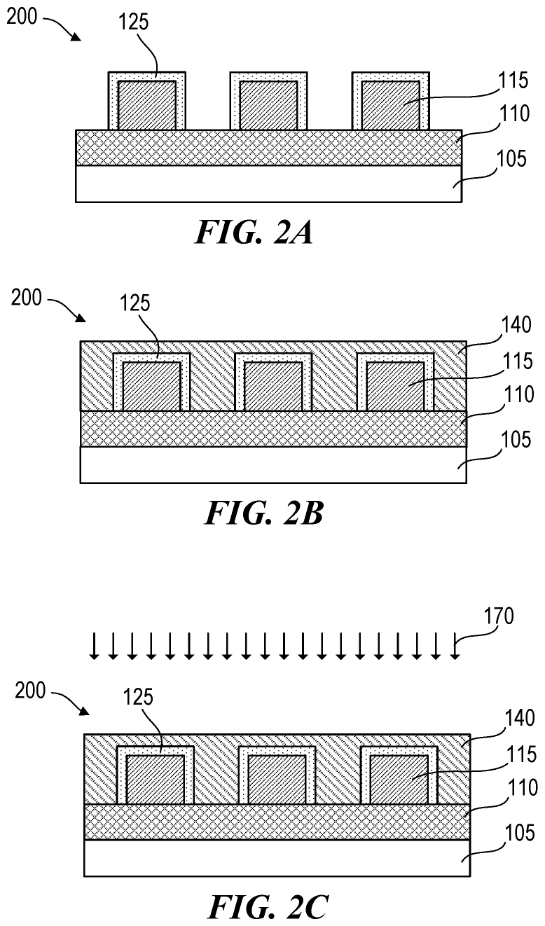

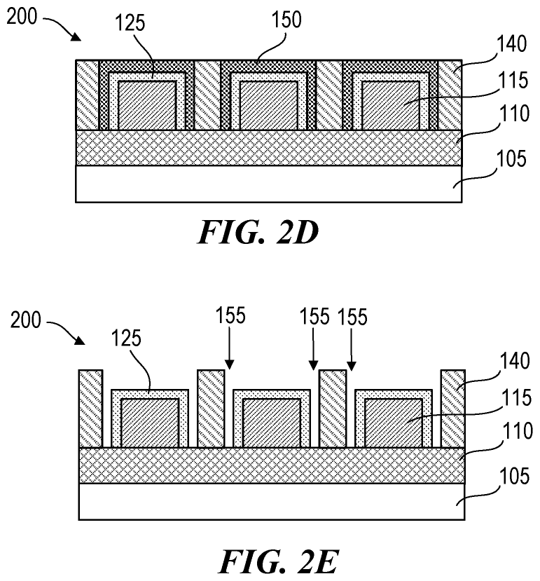

FIGS. 2A-2E show a substrate processing method for forming anti-spacer trenches according to another embodiment. The photoresist pattern 100 in FIG. 1D has been reproduced as photoresist pattern 200 in FIG. 2A.

Next, an organic film, second overcoat 140, is deposited over the photoresist pattern 200 as shown in FIG. 2B, the second overcoat 140 filling openings defined by the photoresist pattern 200 and covering the photoresist pattern 200. The formulation of second overcoat 140 is cast in a solvent or blend of solvents to prevent dissolution of the underlying photoresist or intermixing of the two films. The second overcoat 140 is composed of a resin designed to have a low non-zero dissolution rate in aqueous developer such as tetramethyl ammonium hydroxide to controllably remove the film from overtop the photoresist pattern 200.

After deposition of the second overcoat 140, the substrate undergoes a second lithographic exposure step shown in FIG. 2C. The exposure step exposes the substrate to a second actinic radiation 170 that activates the solubility-shifting agent in the diffusion regions 125 of the photoresist pattern 200. The second actinic radiation 170 can include short wavelength radiation having a wavelength between about 13.5 nm and about 365 nm, for example 266 nm.

Next, post exposure, the activation step further includes baking the substrate as shown in FIG. 2D at an elevated temperature to drive deprotection of the resin via reaction with the photo generated acid diffusing the solubility agent into the second overcoat, resulting in second diffusion regions 150 in the second overcoat 140. The solubility-shifting agent is activated sufficiently to meet the threshold of sensitivity in the second diffusion regions 150 without meeting the threshold of sensitivity of the second overcoat 140.

Next, the substrate is developed with a second developer, resulting in removal of soluble portions of the second diffusion regions 150 of the second overcoat 140, the second overcoat 140 and the diffusion regions 125 in the photoresist pattern 200 being insoluble in the second developer. The removal of the soluble portions of the second diffusion regions 150 of the second overcoat 140 forms anti-spacer features 155 between the remaining diffusion regions 125 in the photoresist pattern 200 and the second overcoat 140. This is shown in FIG. 2E. Thereafter, the method can include transferring the anti-spacer features into the underlying layer 110 through an etching process.

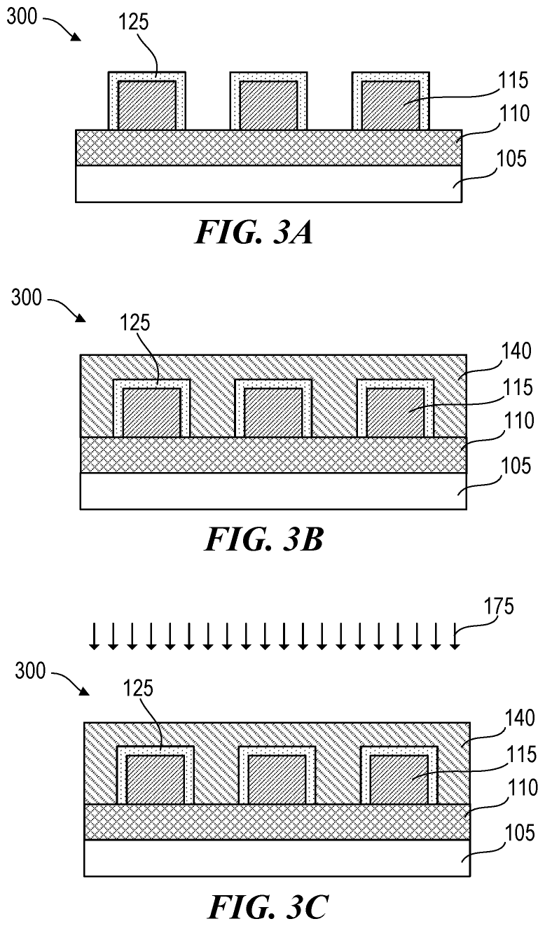

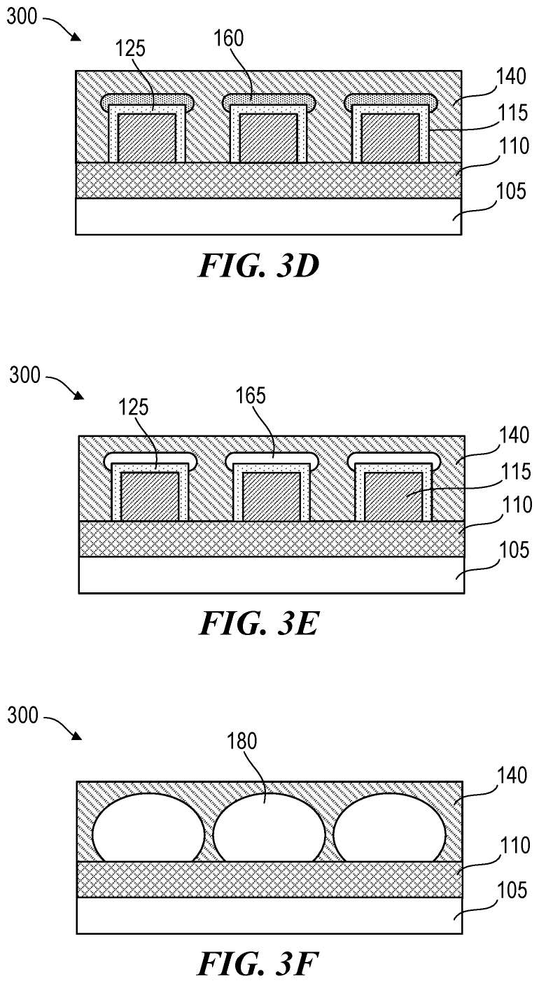

FIGS. 3A-3F show a substrate processing method for forming airgaps in a film according to other embodiments. The photoresist pattern 100 in FIG. 1D has been reproduced as photoresist pattern 300 in FIG. 3A.

Next, an organic film, referred to as second overcoat 140, is deposited over the photoresist pattern 300 as shown in FIG. 3B, the second overcoat 140 filling openings defined by the photoresist pattern 300 and covering the photoresist pattern 300. The formulation of second overcoat 140 is cast in a solvent or blend of solvents to prevent dissolution of the underlying photoresist or intermixing of the two films. The second overcoat 140 is composed of a resin designed to have a low non-zero dissolution rate in aqueous developer such as tetramethyl ammonium hydroxide to controllably remove the film from overtop the photoresist pattern 100.

After deposition of the second overcoat 140, the substrate undergoes a second lithographic exposure step shown in FIG. 3C. The exposure step exposes the substrate to a second actinic radiation 175 that activates the solubility-shifting agent in the diffusion regions 125 of the photoresist pattern 300, especially in the topmost horizontal region of the diffusion regions 125 of the photoresist layer. The second actinic radiation 175 can include long wavelength radiation. The second actinic radiation 175 can include long wavelength radiation having a wavelength between about 300 nm and about 400 nm.

Next, post exposure, the activation step further includes baking the substrate as shown in FIG. 3D at an elevated temperature to drive deprotection of the resin via reaction with the photo generated acid diffusing the solubility agent into the second overcoat 140, resulting in second diffusion regions 160 in the second overcoat 140. The solubility-shifting agent is activated sufficiently to meet the threshold of sensitivity in the second diffusion regions 160 without meeting the threshold of sensitivity of the second overcoat 140.

Next, the substrate is developed with a second developer resulting in removal of soluble portions of the second diffusion regions 160 of the second overcoat 140, the second overcoat 140 and the diffusion regions 125 in the photoresist pattern 300 being insoluble in the second developer. The removal of the soluble portions of the second diffusion regions 160 of the second overcoat 140 forms airgap features 165 between the remaining diffusion regions 125 in the photoresist pattern 300 and the second overcoat 140. This is shown in FIG. 3E.

According to another embodiment, the substrate in FIG. 3D is developed with a second developer resulting in removal of soluble portions of the second diffusion regions 160 of the second overcoat 140, the diffusion regions 125 in the photoresist pattern 300, and the photoresist pattern 300, the second overcoat 140 being insoluble in the second developer. The removal of the soluble portions forms airgap features 180 in the second overcoat 140 as schematically shown in FIG. 3F.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

1. A method of patterning a substrate, the method comprising:
forming a photoresist pattern on the substrate from a layer of photoresist deposited on the substrate, the layer of photoresist including a solubility-shifting agent, the photoresist pattern formed by activating the solubility-shifting agent using a pattern of first actinic radiation, and developing the substrate with a first developer resulting in removal of soluble portions of the layer of photoresist;
depositing a first overcoat on the photoresist pattern, the first overcoat filling openings defined by the photoresist pattern and covering the photoresist pattern, the first overcoat including an organic film containing a dye;
diffusing the dye from the first overcoat a predetermined diffusion length into the photoresist pattern, resulting in diffusion regions in the photoresist pattern;
removing the first overcoat from the substrate;
activating the solubility-shifting agent in the diffusion regions of the photoresist pattern using a second actinic radiation, the solubility-shifting agent activated sufficiently to meet the threshold of sensitivity in the diffusion regions without meeting the threshold of sensitivity of the photoresist pattern;
depositing a second overcoat on the substrate; and
developing the substrate with a second developer resulting in removal of soluble portions of the diffusion regions of the photoresist pattern, the second overcoat being insoluble in the second developer.

2. The method of claim 1, wherein the removal of the soluble portions of the diffusion regions of the photoresist pattern forms anti-spacer features between the remaining photoresist pattern and the second overcoat.

3. The method of claim 2, further comprising:
transferring the anti-spacer features into an underlying layer through an etching process.

4. The method of claim 1, wherein the diffusing the dye from the first overcoat includes baking the substrate.

5. The method of claim 1, wherein the second actinic radiation has a wavelength between about 13.5 nm and about 365 nm.

6. The method of claim 1, wherein the dye includes an acid amplifier.

7. The method of claim 1, wherein the first overcoat and the second overcoat are deposited on the substrate by spin-on deposition.

8. The method of claim 1, wherein the photoresist includes an acid deprotectable resin, a photo-acid generator (PAG) and a quencher.

9. The method of claim 1, wherein the dye reduces the number of PAG-photon interactions within the photoresist pattern.

10. A method of patterning a substrate, the method comprising:
forming a photoresist pattern on the substrate from a layer of photoresist deposited on the substrate, the layer of photoresist including a solubility-shifting agent, the photoresist pattern formed by activating the solubility-shifting agent using a pattern of first actinic radiation, and developing the substrate with a first developer resulting in removal of soluble portions of the layer of photoresist;
depositing a first overcoat on the photoresist pattern, the first overcoat filling openings defined by the photoresist pattern and covering the photoresist pattern, the first overcoat including an organic film containing a dye;
diffusing the dye from the first overcoat a predetermined diffusion length into the photoresist pattern, resulting in first diffusion regions in the photoresist pattern;
removing the first overcoat from the substrate;
depositing a second overcoat on the substrate;
activating the solubility-shifting agent in the first diffusion regions in the photoresist pattern using a second actinic radiation, and diffusing the solubility agent into the second overcoat resulting in second diffusion regions in the second overcoat, the solubility-shifting agent activated sufficiently to meet the threshold of sensitivity in the second diffusion regions without meeting the threshold of sensitivity of the second overcoat; and
developing the substrate with a second developer resulting in removal of soluble portions of the second diffusion regions of the second overcoat, the second overcoat and the first diffusion regions in the photoresist pattern being insoluble in the second developer.

11. The method of claim 10, wherein the removal of the soluble portions of the second diffusion regions of the second overcoat forms anti-spacer features between the remaining first diffusion regions in the photoresist pattern and the second overcoat.

12. The method of claim 10, further comprising:
transferring the anti-spacer features into an underlying layer through an etching process.

13. The method of claim 10, wherein the diffusing the dye from the first overcoat includes baking the substrate.

14. The method of claim 10, wherein the second actinic radiation has a wavelength between about 300 nm and about 400 nm.

15. The method of claim 10, wherein the dye includes an acid amplifier.

16. The method of claim 10, wherein the removal of soluble portions of the second diffusion regions forms airgap features in second overcoat.

17. The method of claim 10, wherein the developing the substrate with the second developer further results in removal of the first diffusion regions in the photoresist pattern and the photoresist pattern.

18. The method of claim 10, wherein the first overcoat and the second overcoat are deposited on the substrate by spin-on deposition.

19. The method of claim 10, wherein the photoresist includes an acid deprotectable resin, a photo-acid generator (PAG) and a quencher.

20. The method of claim 10, wherein the dye reduces the number of PAG-photon interactions within the photoresist pattern.
